(19) United States
(12) Patent Application Publication
(10) Pub. No.: US 2005/0242426 A1
(43) Pub. Date: Nov. 3, 2005

(54) Semiconductor package having a first conductive bump and a second conductive bump and methods for manufacturing the same

(75) Inventors: Heung-Kyu Kwon, Gyeonggi-do (KR); Kyung-Lae Jang, Gyeonggi-do (KR); Hee-Seok Lee, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Suwon-Si (KR)

(21) Appl. No.: 11/110,443

(22) Filed: Apr. 19, 2005

(30) Foreign Application Priority Data
Apr. 30, 2004 (KR) 2004-0030468

(51) Int. Cl. H01L 21/44; H01L 23/48; H01L 23/52

(52) U.S. Cl. 257/690; 438/666

(57) ABSTRACT

In one embodiment, a semiconductor package comprises a base frame and a lower semiconductor chip electrically coupled to the base frame. The lower semiconductor chip has a first bond pad formed on a top surface thereof. The package further includes an upper semiconductor chip overlying the lower semiconductor chip. The upper semiconductor chip has a third bond pad formed on a bottom surface thereof. The package comprises a first conductive bump and a second conductive bump jointly coupling the first bond pad to the third bond pad.

### BACKGROUND OF THE INVENTION

This application claims priority from Korean Patent Application No. 2004-30468, filed on Apr. 30, 2004, the disclosure of which is incorporated herein in its entirety by reference.

1. Field of the Invention

The present invention relates to a semiconductor package and a method of manufacturing the same, and more particularly to a package including upper and lower semiconductor chips interconnected by flip chip bonding, and a method of manufacturing the same.

2. Description of the Related Art

The demand for smaller electronic appliances has required the development of thinner and smaller semiconductor packages which in turn require smaller semiconductor devices. In order to meet the market demand, a System-On-Chip (SOC) configuration and a System-In-Package (SIP) configuration have been suggested for manufacturing semiconductor devices.

A SOC is a semiconductor device in which a plurality of semiconductor chips are integrated into a single semiconductor chip. An SIP is a semiconductor device in which a plurality of individual semiconductor chips are put into a single semiconductor package. In accordance with the SIP process, a plurality of semiconductor chips are horizontally or vertically loaded within a single semiconductor package and have a typical Multi-Chip package (MCP) concept. Generally, a plurality of semiconductor chips are horizontally loaded in the MCP but are vertically stacked in the SIP.

In a printed circuit board of a general electronic appliance, a semiconductor device is mounted with a passive device to improve noise characteristics of the semiconductor device. The passive device includes a capacitor, a resistor, and an inductor. The passive device is mounted as close to the semiconductor device as possible to improve characteristics of the semiconductor device. Accordingly, an SIP in which a passive device, such as a capacitor, and a semiconductor chip, such as a microprocessor, are included has been developed.

A capacitor as the passive device is manufactured using a silicon wafer. The technique of forming a capacitor, using a silicon wafer, is well known. One exemplary technique is disclosed in U.S. patent application Ser. No. 9/386,660 (filed in Aug. 31, 1999), filed by Lucent Technology Co., Ltd.

A semiconductor package and a method of manufacturing the same are disclosed in U.S. Pat. No. 6,057,598 (entitled “Face on Face Flip Chip Integration,” issued on May 2, 2000), assigned to VLSI Technology Inc. In this patent, upper and lower semiconductor chips are interconnected by flip chip bonding technique.

FIG. 1 is a cross-sectional view of a conventional semiconductor package 260.

Referring to FIG. 1, a lower semiconductor chip 212 and an upper semiconductor chip 200 are stacked on a base frame 262 and interconnected with solder bumps 210 interposed between the lower semiconductor chip 212 and the upper semiconductor chip 200 by flip chip bonding. A bond pad 226 placed on an edge of the lower semiconductor chip 212 is electrically connected to a lead (not shown) of the base frame 262 via a wire 264. The upper and lower semiconductor chips 200 and 212, the wires 264, and a portion of the base frame 262 are sealed with a sealing resin 266.

FIGS. 2 through 4 are cross-sectional views illustrating interconnection of the lower semiconductor chip 200 and the upper semiconductor chip 212 by flip chip bonding within the conventional semiconductor package.

Referring to FIG. 2, the solder bumps 210 are formed under the upper semiconductor chip 200. The upper and lower semiconductor chips 200 and 212 are brought together in a direction indicated by arrows A. The upper semiconductor chip 200 has a circuit region 202 and bond pads 208. The lower semiconductor chip 212 has a circuit region 214 and bond pads 224 corresponding to the bond pads 208 of the upper semiconductor chip 200. Furthermore, an additional bond pad 226 for wire bonding is separately formed on the edge of the lower semiconductor chip 212.

FIG. 3 is a cross-sectional view illustrating an upper structure of a bond pad 12 when the solder bump 210 is formed on the bond pad 12 in a conventional semiconductor package. To form the solder bump 210, an insulating layer 16 such as a polyimide film is additionally formed on a passivation layer 14 through which the bond pad 12 is exposed. Furthermore, an Under Bump Metallurgy (UBM) layer 18 connected to the bond pad 12 should be formed. A reference numeral 10 denotes the semiconductor chip.

It is, however, difficult to form the solder bump 210 directly on an aluminum layer or a copper layer generally constituting the bond pad 12. To solve this problem, the UBM layer 18 facilitates bonding of the solder bump 210 to the bond pad 12 and prevents diffusion of the solder bump constituent into the bond pad 12. The UBM layer 18 is typically a multiple metal layer structure comprising an interconnecting layer, a diffusion blocking layer and a wettable layer.

FIG. 4 is an enlarged cross-sectional view of a portion B in FIG. 1.

Referring to FIG. 4, the UBM layer 18 and another UBM layer 18′ are respectively formed on the bond pads 12 and 12′ of the upper semiconductor chip 200 and the lower semiconductor chip 212 to accomplish flip chip bonding using the solder bumps 210. The UBM layer 18′ is formed on the lower semiconductor chip 212 to facilitate bonding of the solder bump 210 that is attached to the upper semiconductor chip 200 and to prevent the diffusion of the solder bump 210 into the bond pad 12′ of the lower semiconductor chip 212.

The flip chip bonding technique using the solder bump 210 may be preferably used for interconnection because a pressure above a prescribed level can be applied to the semiconductor chip during wire bonding, especially when the bond pad is placed on a center portion of the semiconductor chip. Thus, the pressure can damage the circuit region of the semiconductor chip placed on the lower portion of the bond pad.

FIG. 5 is a cross-sectional view illustrating a wire bonded to the lower semiconductor chip 212 (a portion C of FIG. 1) of the semiconductor package shown in FIG. 1. A metal layer 19 that facilitates wire bonding is formed to another bond pad 226 (FIG. 1) disposed on the lower semiconductor chip 212. The metal layer may be composed of composite layers of Ni/Au, Ni/Ag, or Ti/Cu/Ni/Au.

However, in the conventional semiconductor package, a UBM layer is additionally formed in the lower semiconductor chip, which undesirably lengthens the overall manufacturing process time of the SIP and increases manufacturing costs.

### SUMMARY OF THE INVENTION

The present invention provides, among other things, a semiconductor package, with a novel structure for flip chip bonding, thereby eliminating the need for a UBM layer on a semiconductor chip not having a solder bump. The present invention also provides a method of manufacturing a novel semiconductor package such as a system-in-package (SIP).

In one embodiment, a semiconductor package comprises a base frame and a lower semiconductor chip electrically coupled to the base frame. The lower semiconductor chip has a first bond pad formed on a top surface thereof. The package further includes an upper semiconductor chip overlying the lower semiconductor chip. The upper semiconductor chip has a third bond pad formed on a bottom surface thereof. The package comprises a first conductive bump and a second conductive bump jointly coupling the first bond pad to the third bond pad.

### BRIEF DESCRIPTION OF THE DRAWINGS

The above and other features and advantages of the present invention will become more apparent by describing in detail exemplary embodiments thereof with reference to the attached drawings, in which

FIG. 1 is a cross-sectional view of a conventional semiconductor package;

FIGS. 2 through 4 are cross-sectional views illustrating a lower semiconductor chip and an upper semiconductor chip interconnected by flip chip bonding in the conventional semiconductor package shown in FIG. 1;

FIG. 5 is a cross-sectional view illustrating a wire bonded to the lower semiconductor chip in the conventional semiconductor package shown in FIG. 1;

FIG. 6 is a cross-sectional view of a semiconductor package according to an embodiment of the present invention;

FIG. 7 is a cross-sectional view illustrating the lower semiconductor chip and the upper semiconductor chip interconnected by flip chip bonding in the semiconductor package shown in FIG. 6;

FIG. 8 is a cross-sectional view illustrating a wire bonded to the lower semiconductor chip in the semiconductor package shown in FIG. 6;

FIG. 9 is a cross-sectional view of a semiconductor package according to another embodiment of the present invention;

FIG. 10 is a cross-sectional view illustrating the lower semiconductor chip and the upper semiconductor chip interconnected by flip chip bonding in the semiconductor package shown in FIG. 9;

FIG. 11 is a cross-sectional view illustrating a wire bonded to the lower semiconductor chip in the semiconductor package shown in FIG. 9;

FIG. 12 is a cross-sectional view of a semiconductor package according to yet another embodiment of the present invention;

FIG. 13 is a cross-sectional view illustrating the lower semiconductor chip and the upper semiconductor chip interconnected by flip chip bonding in the semiconductor package shown in FIG. 12;

FIG. 14 is a cross-sectional view illustrating a wire bonded to the lower semiconductor chip in the semiconductor package shown in FIG. 12;

FIG. 15 is a cross-sectional view of a semiconductor package according to still another embodiment of the present invention;

FIG. 16 is a cross-sectional view illustrating the lower semiconductor chip and the upper semiconductor chip interconnected by flip chip bonding in the semiconductor package shown in FIG. 15;

FIG. 17 is a cross-sectional view illustrating a wire bonded to the lower semiconductor chip in the semiconductor package shown in FIG. 15;

FIG. 18 is a plan view illustrating a structure of the base frame, the lower semiconductor chip and the upper semiconductor chip of the semiconductor package according to an embodiment of the present invention; and

FIG. 19 is a cross-sectional view illustrating a semiconductor package according to an embodiment of the present invention.

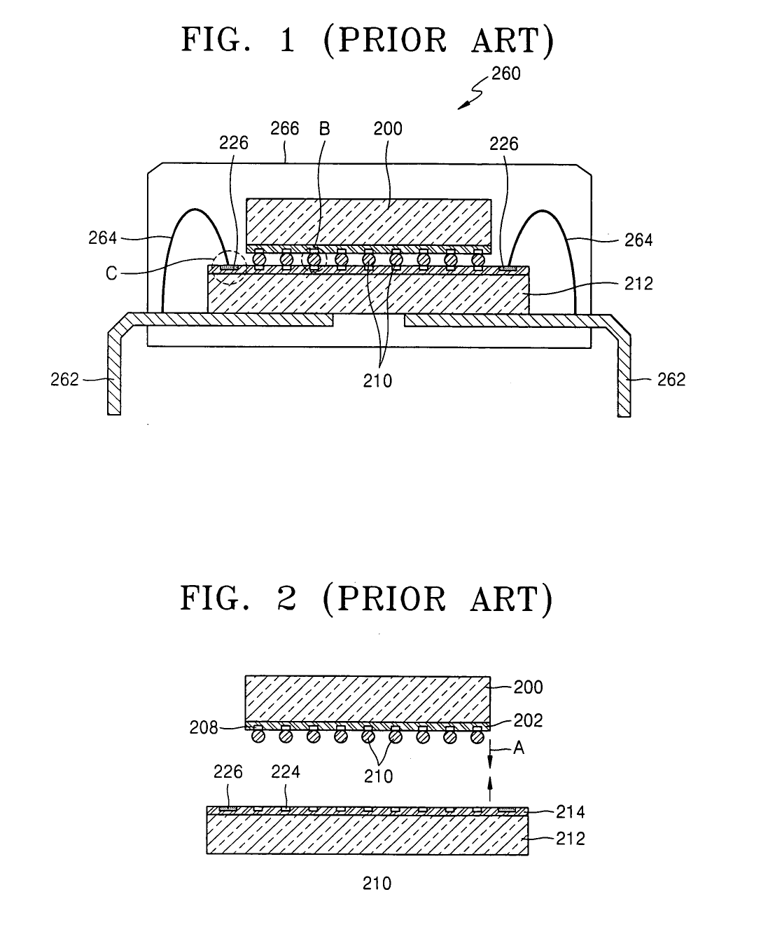

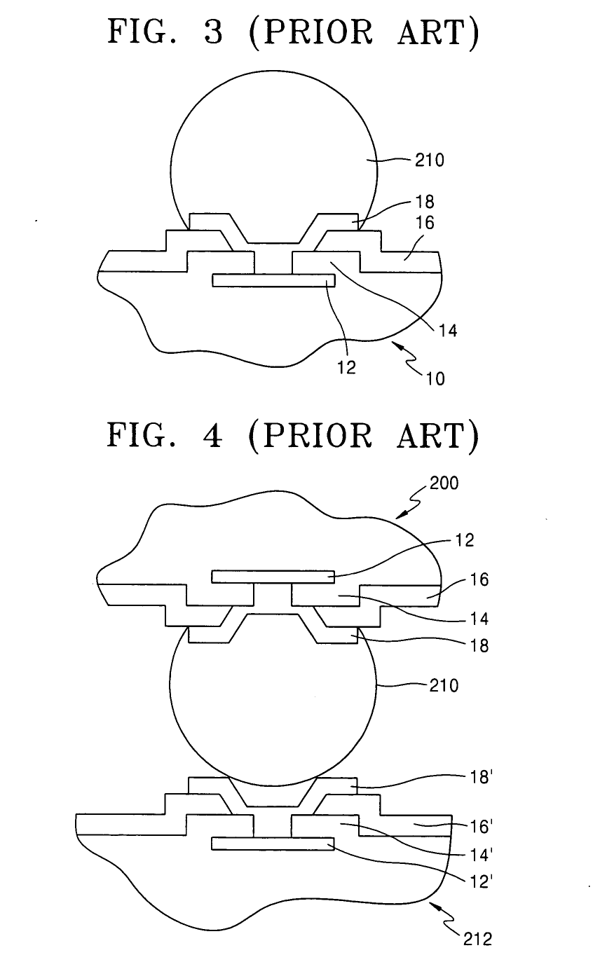

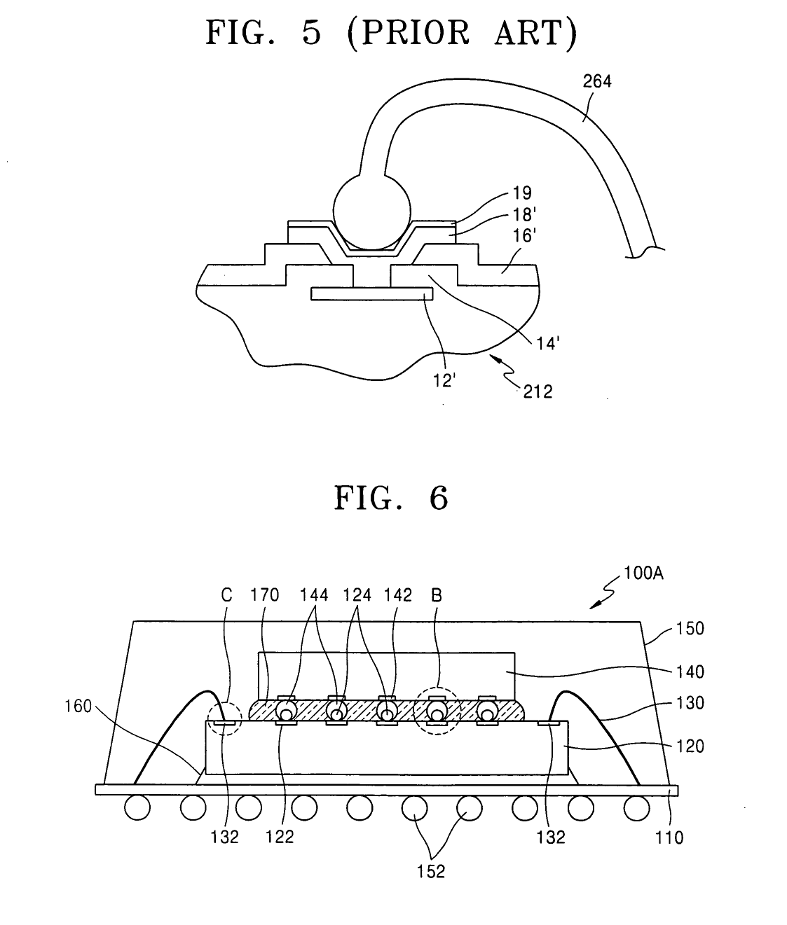

### DETAILED DESCRIPTION OF THE PREFERRED EMBODIMENTS

The present invention will now be described more fully with reference to the accompanying drawings. The invention may, however, be embodied in many different forms and should not be construed as being limited to the embodiments set forth herein; rather these embodiments are provided so that this disclosure will be thorough and complete, and will fully convey the concept of the invention to those skilled in the art.

Referring to FIG. 6, a semiconductor package, e.g., an SIP 100A according to an embodiment of the present invention includes a base frame 110. A lower semiconductor chip 120 is attached to a chip pad of the base frame 110 by, for example, an adhesive 160. A first bond pad 122 is formed on a central portion of the upper surface of the lower semiconductor chip 120 for flip chip interconnection, and a second bond pad 132 is formed on an edge portion or a peripheral area of the upper surface of the lower semiconductor chip 120. Additionally, the lower semiconductor chip 120 includes a conductive bump 124, e.g., a gold bump, formed on the first bond pad 122. The conductive bump 124 may be formed as stud- like or other suitable structures for interconnection.

The SIP 100A may include a wire 130 electrically connecting the second bond pad 132 of the lower semiconductor chip 120 to the base frame 110. Also, an upper semiconductor chip 140 mounted on the lower semiconductor chip 120 includes another conductive bump 144, e.g., a solder bump, disposed on a third bond pad 142 to be coupled to the gold bump 124 on the first bond pad 122 of the lower semiconductor chip 120. A sealing resin 150 may tightly seal a portion of the base frame 110, the wires 130, the lower semiconductor chip 120 and the upper semiconductor chip 140.

A space between the interconnected lower semiconductor chip 120 and the upper semiconductor chip 140 may be filled with the sealing resin 150, or an underfill material 170 such as epoxy to enhance the reliability of the interconnection.

The gold bump 124 can be easily formed on the first bond pad 122 using wire bonding equipment during a semiconductor assembly process. The gold bump 124 eliminates the need for a UBM layer over the second bond pad 132. That is, a UBM layer needs not be formed on the lower semiconductor chip 120 while using the conventionally employed first and second bond pads 122 and 132. Thus, overall manufacturing process time can be shortened and manufacturing costs can be decreased.

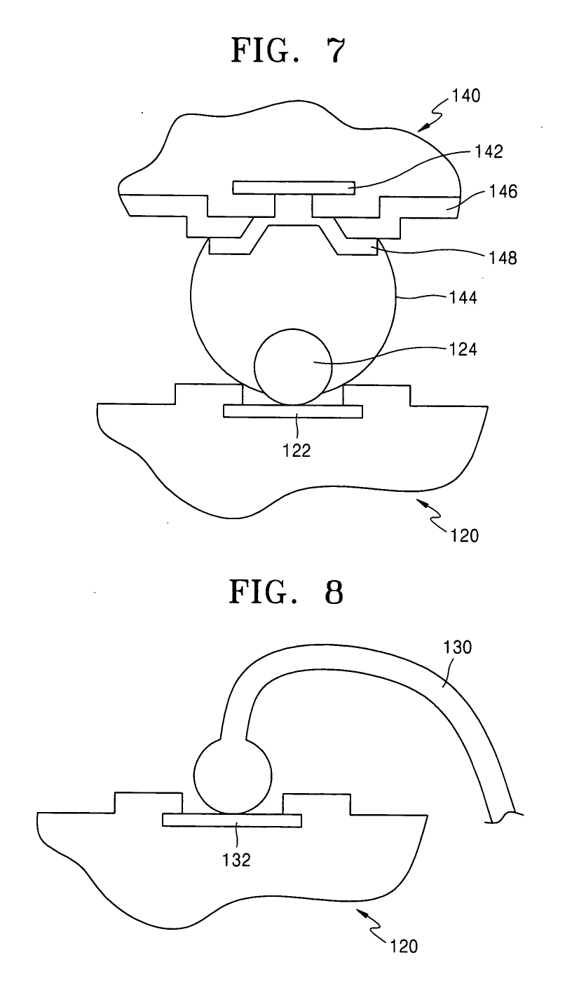

FIG. 7 is a cross-sectional view illustrating interconnection of the lower semiconductor chip 120 and the upper semiconductor chip 140 using a flip chip technique in the SIP. FIG. 8 is a cross-sectional view illustrating a wire 130 bonded to the lower semiconductor chip 120.

Referring to FIGS. 7 and 8, in the SIP 100A according to this embodiment of the present invention, flip chip bonding may be accomplished by connecting the stud-like gold bump 124 to the solder bump 144. The upper semiconductor chip 140 having the solder bump 144 is subjected to UBM treatment in which an insulating layer 146 and a UBM layer 148 are formed. However, UBM treatment is not required on the lower semiconductor chip 120 having the gold bump 124. Also, the wire 130 connecting the lower semiconductor chip 120 with the base frame 110 is directly connected to aluminum constituting the second bond pad 132. The wire 130 may be composed of Au, Ag or Cu.

Referring to FIG. 6, a method of manufacturing the SIP 100A according to an embodiment of the present invention will now be described.

A flexible printed circuit board (PCB) or a rigid type PCB may be used as the base frame 110. A base frame generally employed for a ball grid array (BGA) may be used as the base frame 110. Then, the lower semiconductor chip 120 is mounted on the base frame 110, preferably, using the adhesive 160 such as an adhesive tape or epoxy. The first bond pad 122 suitable for flip chip bonding is formed on the central portion of the lower semiconductor chip 120, and the second bond pad 132 for wire bonding is formed on the edge portion of the lower semiconductor chip 120. The gold bump 124 is formed on the first bond pad 122. The lower semiconductor chip 120 may act as a microprocessor, an LSI, or a logic device.

The gold bump 124 may be formed in a wafer fabrication process or in a semiconductor chip state after mounting the lower semiconductor chip 120 on the base frame 110.

Subsequently, the second bond pad 132 of the lower semiconductor chip 120 is electrically connected to a bond finger (112 of FIG. 18) of the base frame 110 by electrical connection means such as the bonding wire 130. The wire bonding may be performed after loading the upper semiconductor chip 140.

The upper semiconductor chip 140 having the third bond pad 142 corresponding to the first bond pad 122 of the lower semiconductor chip 120, and the solder bump 144 on the third bond pad 142 is prepared. The third bond pad 142 of the upper semiconductor chip 140 is formed with the UBM layer 148 and the insulating layer 146 to facilitate interconnection of the solder bump 144 and to prevent diffusion.

Then, the gold bump 124 of the lower semiconductor chip 120 is placed in contact with the solder bump 144 of the upper semiconductor chip 140 by flip chip bonding, thereby mounting the upper semiconductor chip 140 on the lower semiconductor chip 120. After mounting the upper semiconductor chip 140, an under-fill material, such as liquid-state epoxy, is filled between the lower semiconductor chip 120 and the upper semiconductor chip 140 to improve reliability of the interconnection, and is hardened to form the underfill 170.

Thereafter, a portion of the base frame 110, the wires 130, and the lower and upper semiconductor chips 120 and 140 may be sealed by the sealing resin 150. Finally, the solder ball 152 is attached to a solder-ball pad (not shown) disposed below the base frame 110, and a singulation process of individually separating the SIP 100A manufactured in a matrix form is performed.

Referring back to FIG. 6, another method of manufacturing the SIP will now be described. Here, the lower semiconductor chip 120 and the upper semiconductor chip 140 are interconnected first, and the interconnected structure is then mounted on the base frame 110.

In further detail, the lower semiconductor chip 120 is formed with the first bond pad 122 on the central portion, and the second bond pad 132 on the peripheral portion. The upper semiconductor chip 140 is formed with the third bond pad 142 corresponding to the first bond pad 122 thereon. The stud-like gold bump 124 is formed on the first bond pad 122, and the solder bump 144 is formed on the third bond pad 142.

The gold bump 124 of the lower semiconductor chip 120 and the solder bump 144 of the upper semiconductor chip 140 are placed in contact with each other. Then, the mutually interconnected lower semiconductor chip 120 and upper semiconductor chip 140 are mounted on the base frame 110 using the adhesive 160. The lower semiconductor chip 120 and the upper semiconductor chip 140 may be subjected to flux cleaning immediately after interconnecting the lower semiconductor chip 120 with the upper semiconductor chip 140, or after mounting the interconnected lower semiconductor chip 120 and upper semiconductor chip 140 on the base frame 110.

The space between the lower semiconductor chip 120 and the upper semiconductor chip 140 is filled with the liquid-state epoxy, which is hardened to form the underfill 170 to improve the reliability of the interconnection.

Thereafter, the second bond pad 132 of the lower semiconductor chip 120 and the base frame 110 are electrically connected by the wire 130. The base frame 110, the wires 130, and the lower and upper semiconductor chips 120 and 140 may be sealed using the sealing resin 150. Finally, the solder balls 152 are attached to the lower portion of the base frame 110, and a singulation process of individually separating the SIP 100A manufactured in a matrix form is performed.

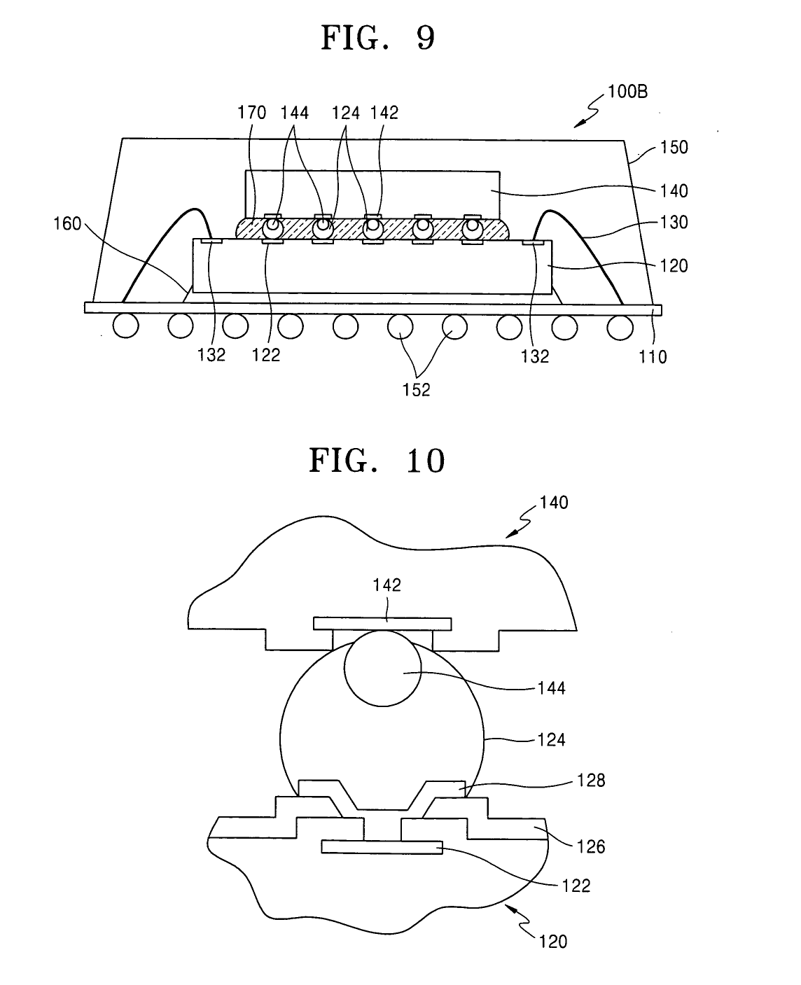

Now another embodiment will be described, having a stud-like gold bump applied to an upper semiconductor chip. FIG. 9 is a cross-sectional view of an SIP according to this embodiment of the present invention.

Referring to FIG. 9, the SIP 100B includes a base frame 110 on which semiconductor chips can be mounted. A lower semiconductor chip 120 is attached to a chip pad of the base frame 110 using an adhesive 160, and a first bond pad 122 for flip chip bonding is formed on a central portion of the lower semiconductor chip 120 and a second bond pad 132 is formed on an edge portion of the lower semiconductor chip 120. A solder bump 124 is formed on the first bond pad 122 of the lower semiconductor chip 120.

The SIP 100B also includes a wire 130 that electrically connects the second bond pad 132 of the lower semiconductor chip 120 to the base frame 110, and an upper semiconductor chip 140 stacked on the lower semiconductor chip 120. A third bond pad 142 of the upper semiconductor chip 140 is formed with a gold bump 144 in contact with the solder bump 124 of the lower semiconductor chip 120.

Also, the SIP 100B includes a sealing resin 150 that tightly seals a portion of the base frame 110, the wires 130, the lower semiconductor chip 120, and the upper semiconductor chip 140. An underfill 170 is formed between the lower semiconductor chip 120 and the upper semiconductor chip 140. The third bond pad 142 of the upper semiconductor chip 140 formed with the stud-like gold bump 144 eliminates the need for UBM treatment.

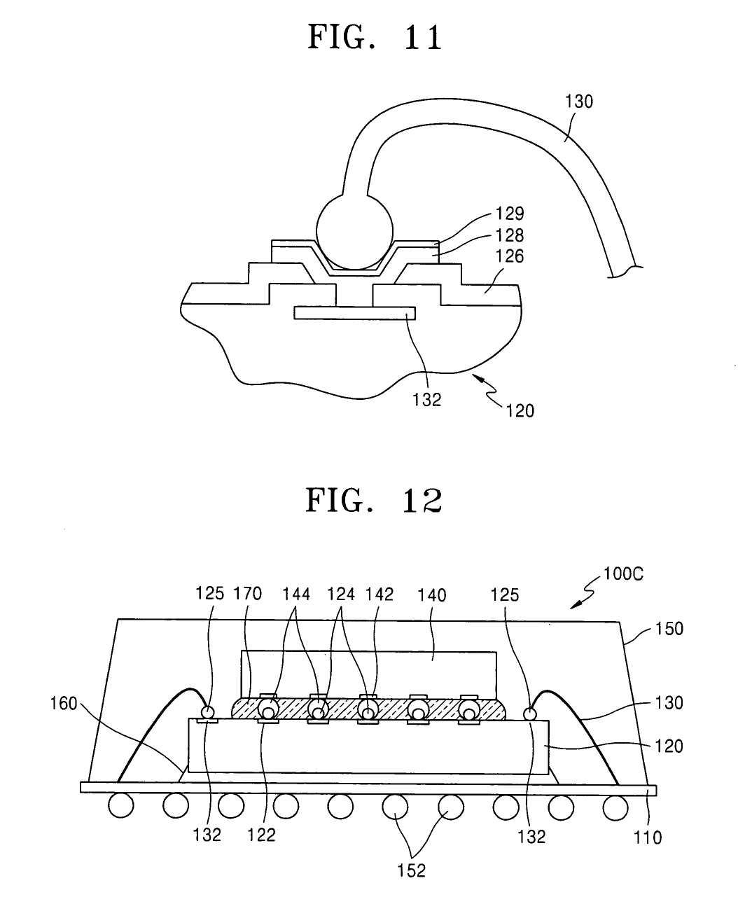

FIG. 10 is a cross-sectional view illustrating flip chip bonding of the lower semiconductor chip 120 and the upper semiconductor chip 140 in the SIP according to the embodiment of the present invention. FIG. 11 is a cross-sectional view illustrating a wire 130 bonded to the lower semiconductor chip 120.

Referring to FIGS. 10 and 11, the flip chip bonding is obtained by contacting the stud-like gold bump 144 of the upper semiconductor chip 140 with the solder bump 124 formed on the lower semiconductor chip 120. The lower semiconductor chip 120 having the solder bump 124 is subjected to UBM treatment. That is, the lower semiconductor chip 120 includes an insulating layer 126 and a UBM layer 128.

A metal layer 129 is formed on the UBM layer 128 to help facilitate the wire bonding process. The metal layer 129 can be composed of a composite layer of Ni/Au, Ni/Ag or Ni/Pd. The wire 130 may be Au, Ag, or Cu.

Hereinafter, a method of manufacturing the SIP 100B according to this embodiment of the present invention will be described with reference to FIG. 9.

A flexible PCB or a rigid PCB is prepared as the base frame 110. The lower semiconductor chip 120 is attached to the base frame 110 using the adhesive 160 such as an adhesive tape or epoxy. The first bond pad 122 suitable for flip chip bonding is formed on the central portion of the lower semiconductor chip 120, and the second bond pad 132 for wire bonding is formed on the edge portion of the lower semiconductor chip 120. The solder bump 124 is formed on the first bond pad 122. The lower semiconductor chip 120 may be a microprocessor, a LSI and a logic device while the upper semiconductor chip 140 may be a capacitor device.

Subsequently, the second bond pad 132 of the lower semiconductor chip 120 is electrically connected to the bond finger 112 (of FIG. 18) of the base frame 110 by wire bonding. This process can also be performed after mounting the upper semiconductor chip 140.

Then, the upper semiconductor chip 140 having the third bond pad 142 corresponding to the first bond pad 122 of the lower semiconductor chip 120, and the gold bump 144 disposed on the third bond pad 142 is prepared. The gold bump 144 can be formed in a wafer fabricating process. The third bond pad 142 of the upper semiconductor chip 140 may not include a UBM layer.

Thereafter, the solder bump 124 of the lower semiconductor chip 120 and the gold bump 144 of the upper semiconductor chip 140 are interconnected by flip chip bonding, thereby mounting the upper semiconductor chip 140 on the lower semiconductor chip 120. After mounting the upper semiconductor chip 140, a liquid-state epoxy is filled between the lower semiconductor chip 120 and the upper semiconductor chip 140, and is hardened to form the underfill 170 to improve the reliability of the interconnection.

The base frame 110, the wires 130, and the lower and upper semiconductor chips 120 and 140 are sealed by the sealing resin 150. Finally, the solder balls 152 are attached to a lower portion of the base frame 110, and the SIP 100B manufactured in a matrix form are singulated.

A method of manufacturing the SIP 100B according to another embodiment of the present invention will now be described with reference to FIG. 9. At this time, the lower semiconductor chip 120 and the upper semiconductor chip 140 are interconnected first. Then, the resultant structure is loaded on the base frame 110.

In particular, the lower semiconductor chip 120 and the upper semiconductor chip 140 are prepared. At this time, the lower semiconductor chip 120 has the first bond pad 122 on the central portion and the second bond pad 132 on the edge portion. The upper semiconductor chip 140 has the third bond pad 142 corresponding to the first bond pad 122. The solder bump 124 is formed on the first bond pad 122 and the stud-like gold bump 144 is formed on the third bond pad 142.

The solder bump 124 of the lower semiconductor chip 120 and the gold bump 144 of the upper semiconductor chip 140 are placed in contact with each other. The mutually interconnected lower semiconductor chip 120 and upper semiconductor chip 140 are mounted on the base frame 110 using the adhesive 160. The lower semiconductor chip 120 and the upper semiconductor chip 140 may be flux cleaned immediately after being interconnected or after the already interconnected upper and lower semiconductor chips 140 and 120 are mounted on the base frame 110.

To improve reliability of the interconnection, the liquid-state epoxy is filled between the lower semiconductor chip 120 and the upper semiconductor chip 140, which is then hardened to form the underfill 170.

Thereafter, the wire 130 is electrically connected to the second bond pad 132 including the metal layer 129 for facilitating wire bonding to the base frame 110. The base frame 110, the wires 130, and the lower and upper semiconductor chips 120 and 140 are sealed or encapsulated, using the sealing resin 150 or other suitable encapsulants. Finally, the solder balls 152 are attached to the lower portion of the base frame 110, and the SIP 100B manufactured in a matrix form are singulated, i.e., individually separated.

Now still another embodiment will be described that has an electro-plated gold bump applied to a lower semiconductor chip.

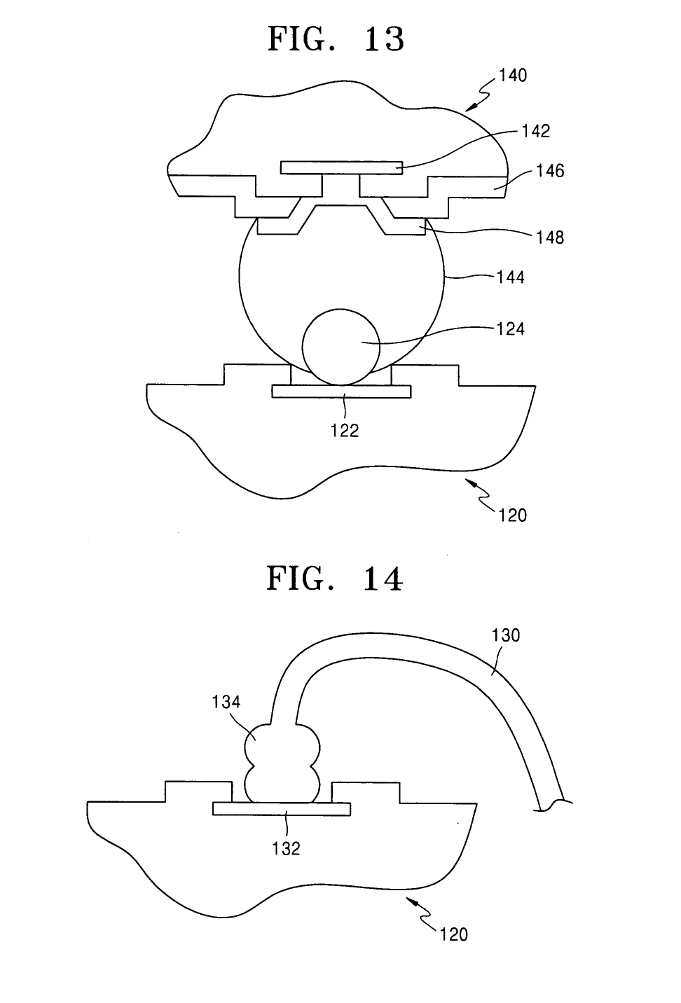

FIG. 12 is a cross-sectional view of an SIP according this embodiment of the present invention. FIG. 13 is a cross-sectional view illustrating flip chip bonding of the lower semiconductor chip 120 and the upper semiconductor chip 140, and FIG. 14 is a cross-sectional view illustrating a wire bonded to the lower semiconductor chip 120.

Referring to FIGS. 12, 13 and 14, the structure and method of manufacturing the SIP 100C according to this embodiment of the present invention are similar to those of the first embodiment described above. The descriptions of identical portions will thus be omitted for simplicity.

As opposed to the first embodiment described, the gold bump 125 disposed on the lower semiconductor chip 120 in the third embodiment is formed by electroplating. The gold bump 125 is formed on the second bond pad 132 on the edge of the lower semiconductor chip 120 and on the first bond pad 122 of the lower semiconductor chip 120. Therefore, wire bonding to connect the lower semiconductor chip 120 to the base frame 110 is performed on the gold bump 125 disposed on the second bond pad 132. Therefore, the wire-bonded gold bump 134 has the shape of two stacked ball bonds.

As in the first embodiment described, UBM treatment is performed on the upper semiconductor chip 140, but is not required for the lower semiconductor chip 120. Therefore, the process is simplified and manufacturing costs are decreased.

Now yet another embodiment will be described, having an electro-plated gold bump applied to an upper semiconductor chip 140.

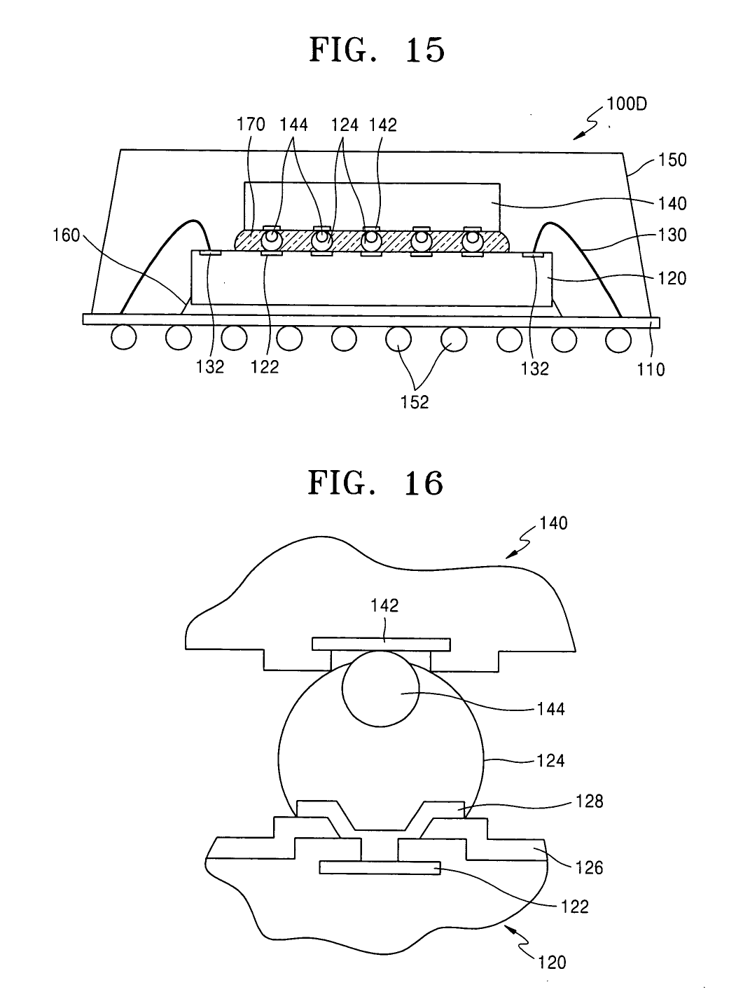

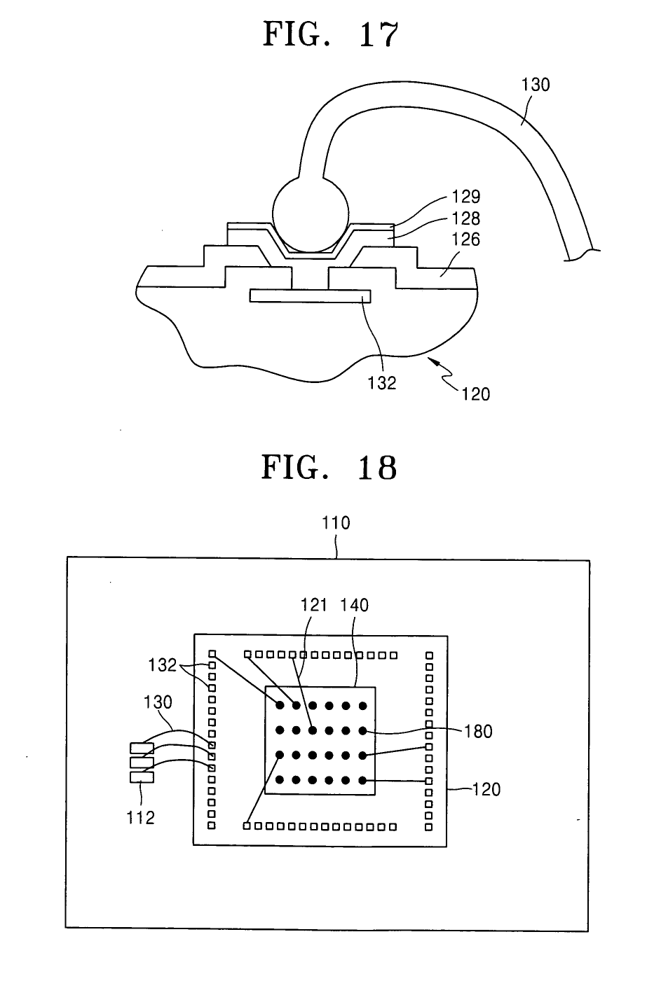

FIG. 15 is a cross-sectional view of an SIP according to this embodiment of the present invention. FIG. 16 is a cross-sectional view illustrating flip chip bonding of the lower semiconductor chip and the upper semiconductor chip, and FIG. 17 is a cross-sectional view illustrating a wire bonded to the lower semiconductor chip.

Referring to FIGS. 15, 16 and 17, the structure and method of manufacturing the SIP 100D according to this embodiment of the present invention are similar to those of the embodiment described in connection with FIG. 9. The descriptions of identical portions will thus be omitted for simplicity.

In contrast with the embodiment shown in FIG. 9, a gold bump 144 disposed on a third bond pad 142 of an upper semiconductor chip 140 is formed by electro-plating. As in the embodiment of FIG. 9, the lower semiconductor chip 120 is subjected to UBM treatment, which is not performed to the upper semiconductor chip 140. Therefore, the process is simplified and manufacturing costs are decreased.

FIG. 18 is a plan view illustrating a structure of the base frame, the lower semiconductor chip and the upper semiconductor chip in the SIP according to embodiments of the present invention.

Referring to FIG. 18, the lower semiconductor chip 120 is mounted on the base frame 110. The upper semiconductor chip 140 is mounted on the lower semiconductor chip 120. The second bond pad 132 disposed on the lower semiconductor chip 120 is electrically connected to the bond finger 112 on the base frame 110 via the wire 130. The material and structure of the flip chip interconnection 180 of the lower and upper semiconductor chips 120 and 140 according to embodiments of the present invention are characterized by the solder bump and the gold bump contact.

The upper semiconductor chip 140 may be a passive device for improving noise characteristics of the semiconductor device. A method of manufacturing the passive device is well known, and an example of such a method is disclosed in U.S. patent application Ser. No. 9/386660 (filed on Aug. 31, 1999, by Lucent Technology. Co. Ltd), of which detailed description is omitted for simplicity.

Also, the first bond pad 122 on the central portion of the lower semiconductor chip 120 may be connected to the second bond pad 132 by inner circuit line 121. The inner circuit line 121 connecting the first and second bond pads 122 and 132 may be formed during or after a wafer manufacturing process for forming a wafer level package (WLP).

Consequently, power terminals and ground terminals of the upper semiconductor chip 140 serving as a capacitor may be connected to the second bond pads 132 via the first bond pads 122. Also, the second bond pads 132 may be connected to the bond fingers 112 of the base frame 110 via the wires 130. The bond fingers 112 may be externally connected via the solder balls (not shown) attached to the lower surfaces of the base frame 110.

As a result, the upper semiconductor chip 140 functioning as a capacitor may be loaded adjacent to the lower semiconductor chip 120 functioning as a microprocessor, an LSI device, or a logic device, thereby embodying an SIP capable of improving noise characteristics of the lower semiconductor chip 120.

In still another embodiment a lead frame may be used as a base frame.

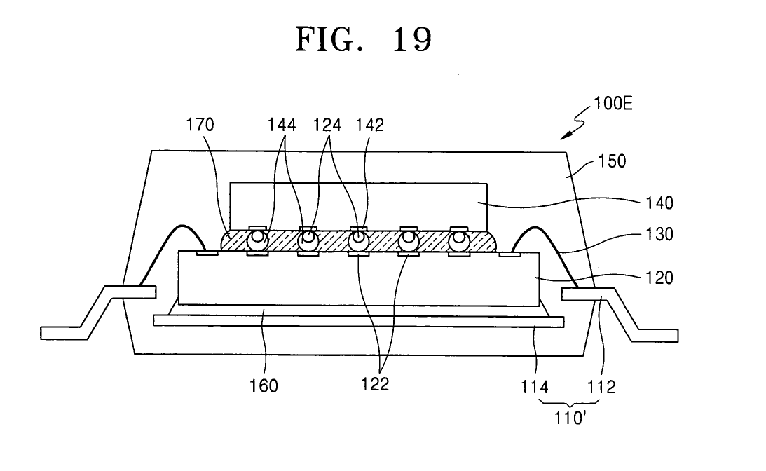

FIG. 19 is a cross-sectional view of the SIP according to one embodiment of the present invention. In the previously described embodiments, the base frame 110 may be a flexible PCB or a rigid PCB. However, the SIP 100E includes a lead frame 110′ in place of the PCB included in the above-described embodiments. The lead frame 110′ includes a chip pad 114 and a lead 112. The SIP 100E may enable various packages such as a Thin Small Out-Line Package (TSOP), a Thin Quad Flat Package (TQFP), and a Quad Flat No-lead Package (QFN) depending on the shapes of the lead frame 110′. In this case, after the encapsulation or sealing, the leads 112 externally exposed from the sealing resin 150 may be lead bar trimmed, lead plated, or lead forming. Furthermore, the present invention is applicable to a Pin Grid Array (PGA) package in which pins are connected to a lower surface of the base frame 110 instead of using the solder balls.

As described above, with embodiments of the present invention, there is no need to perform UBM treatment on a semiconductor chip having a gold bump. Therefore, manufacturing costs of the SIP can be decreased, and the manufacturing process can be simplified.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor package comprising:
a base frame;
a lower semiconductor chip electrically coupled to the base frame, the lower semiconductor chip having a first bond pad formed on a top surface thereof;
an upper semiconductor chip overlying the lower semiconductor chip, the upper semiconductor chip having a third bond pad formed on a bottom surface thereof; and
a first conductive bump and a second conductive bump jointly coupling the first bond pad to the third bond pad.

2. The package of claim 1, wherein the first bond pad is formed on a central portion of the lower semiconductor chip and wherein a second bond pad is formed on a periphery of the lower semiconductor chip, the second bond pad electrically connected to the base frame.

3. The package of claim 1, wherein the second conductive bump is disposed within the first conductive bump.

4. The package of claim 1, wherein the first conductive bump is coupled to the first bond pad, and wherein the second conductive bump is coupled to the third bond pad.

5. The package of claim 4, wherein the first conductive bump comprises solder and the second conductive bump comprises gold.

6. The package of claim 5, wherein a UBM layer is not formed on the third bond pad.

7. The package of claim 5, further comprising a metal layer formed on a surface of the second bond pad.

8. The package of claim 7, wherein the metal layer is a composite layer of Ni/Au, Ni/Ag, or Ni/Pd.

9. The package of claim 4, wherein the first conductive bump comprises gold and the second conductive bump comprises solder.

10. The package of claim 9, wherein a UBM layer is not formed on the first and second bond pads.

11. The package of claim 1, further comprising
a sealing resin sealing a portion of the base frame, the lower semiconductor chip, and the upper semiconductor chip.

12. The package of claim 1, wherein the base frame is a flexible printed circuit board (PCB), a rigid PCB, or a lead frame.

13. The package of claim 1, wherein one of the lower semiconductor chip and the upper semiconductor chip acts as a capacitor.

14. The package of claim 1, wherein one of the first or second conductive bump comprises a gold bump formed by electroplating or studding.

15. The package of claim 1, further comprising an underfill filling a space between the lower semiconductor chip and the upper semiconductor chip.

16. The package of claim 1, further comprising solder balls attached to a bottom surface of the base frame.

17. The package of claim 1, wherein the first and second bond pads are electrically connected to each other.

18. A method of manufacturing a package comprising:
providing a base frame;
providing a lower semiconductor chip having a first bond pad on a central portion of the lower semiconductor chip and a second bond pad on a periphery of the lower semiconductor chip;
mounting the lower semiconductor chip on the base frame;
providing an upper semiconductor chip having a third bond pad corresponding to the first bond pad of the lower semiconductor chip; and
mounting the upper semiconductor chip on the lower semiconductor chip by coupling the third bond pad to the first bond pad using a first conductive bump and a second conductive bump together.

19. The method of claim 18, further comprising electrically connecting the second bond pad to the base frame.

20. The method of claim 18, wherein the second conductive bump is disposed within the first conductive bump.

21. The method of claim 18, further comprising sealing a portion of the base frame, and the lower and upper semiconductor chips using a sealing resin.

22. The method of claim 18, wherein the base frame is a flexible PCB, a rigid type PCB or a lead frame.

23. The method of claim 18, wherein mounting the lower semiconductor chip on the base frame comprises using an adhesive tape or epoxy.

24. The method of claim 18, wherein the second conductive bump is formed on the upper semiconductor chip, and wherein the first conductive bump is formed on the lower semiconductor chip.

25. The method of claim 24, wherein the second conductive bump comprises solder and the first conductive bump comprises gold.

26. The method of claim 25, wherein a UBM layer is not formed on the first and second bond pads.

27. The method of claim 24, wherein the second conductive bump comprises gold and the first conductive bump comprises solder.

28. The method of claim 27, wherein a UBM layer is not formed on the third bond pad.

29. The method of claim 27, further comprising forming a metal layer on a surface of the second bond pad to facilitate wire bonding.

30. The method of claim 29, wherein the metal layer comprises a composite layer of Ni/Au, Ni/Ag, or Ni/Pd.

31. The method of claim 18, further comprising, after mounting the upper semiconductor chip on the lower semiconductor chip:
filling a liquid-state under-fill material between the lower semiconductor chip and the upper semiconductor chip; and
hardening the liquid-state under-fill material.

32. The method of claim 18, wherein one of the lower semiconductor chip and the upper semiconductor chip acts as a capacitor.

33. The method of claim 18, wherein one of the first conductive bump and the second conductive bump comprises gold formed by studding.

34. The method of claim 33, wherein the gold bump is formed in a wafer fabrication process before mounting the lower semiconductor chip on the base frame.

35. The method of claim 33, wherein the gold bump is formed after mounting the lower semiconductor chip on the base frame.

36. The method of claim 33, wherein the gold bump is formed by electroplating.

37. The method of claim 33, wherein the electroplated gold bump is formed on both the first and second bond pads.

38. The method of claim 21, further comprising, after the sealing, attaching solder balls to solder ball pads disposed on a lower surface of the base frame.

39. The method of claim 21, further comprising, after the sealing, processing leads externally exposed from the sealing resin.

40. A method of manufacturing a package, the method comprising:
preparing a lower semiconductor chip having a first bond pad on a central portion thereof, and an upper semiconductor chip having a third bond pad corresponding to the first bond pad of the lower semiconductor chip;
electrically connecting the first bond pad of the lower semiconductor chip to the third bond pad of the upper semiconductor chip using a first conductive bump and a second conductive bump together; and
mounting the electrically connected upper semiconductor chip and the lower semiconductor chip on a base frame.

41. The method of claim 40, wherein a second bond pad is formed on an edge portion of the lower semiconductor chip, further comprising electrically connecting the second bond pad to the base frame.

42. The method of claim 40, further comprising sealing a portion of the base frame, the wires, and the lower and upper semiconductor chips.

43. The method of claim 40, further comprising, after electrically connecting the lower semiconductor chip and the upper semiconductor chip, flux cleaning.

44. The method of claim 43, further comprising, after the flux cleaning:
filling a liquid-state under-fill material between the lower semiconductor chip and the upper semiconductor chip; and
hardening the liquid-state under-fill material.

45. The method of claim 40, wherein the base frame is a flexible PCB, a rigid type PCB, or a lead frame.

46. The method of claim 40, wherein the second conductive bump is formed on the upper semiconductor chip, and wherein the first conductive bump is formed on the lower semiconductor chip.

47. The method of claim 46, wherein the first conductive bump comprises gold and the second conductive bump comprises solder.

48. The method of claim 47, wherein a UBM layer is not formed on the first and second bond pads.

49. The method of claim 46, wherein the first conductive bump comprises solder, and wherein the second conductive bump comprises gold.

50. The method of claim 49, wherein a UBM layer is not formed on the third bond pad.

51. The method of claim 49, further comprising forming a metal layer on a surface of the second bond pad to facilitate wire bonding.

52. The method of claim 51, wherein the metal layer is a composite layer of Ni/Au, Ni/Ag, or Ni/Pd.

53. The method of claim 40, wherein either one of the lower semiconductor chip and the upper semiconductor chip acts as a capacitor.

54. The method of claim 40, wherein one of the first conductive bump and the second conductive bump comprises gold formed by electroplating or studding.

55. The method of claim 54, wherein the electroplated gold bump is formed on both the first and second bond pads.

56. The method of claim 42, further comprising, after the sealing, attaching solder balls to a solder ball pad disposed on a lower surface of the base frame.

57. The method of claim 42, further comprising, after the sealing, processing leads externally exposed from the sealing resin.
